(19) United States
(12) Patent Application Publication
(10) Pub. No.: US 2011/0181295 A1
(43) Pub. Date: Jul. 28, 2011

(54) FAULT DETECTION USING COMBINED REFLECTOMETRY AND ELECTRONIC PARAMETER MEASUREMENT

(75) Inventors: Michael Lee Haugen, Alpine, UT (US); Michael Paul Masquelier, Park City, UT (US); James Craig Stephenson, Salt Lake City, UT (US); Michael Paul Diamond, Sandy, UT (US); Steven Andrew Kerr, West Valley City, UT (US)

(73) Assignee: LIVEWIRE TEST LABS, INC., Salt Lake City, UT (US)

(21) Appl. No.: 13/009,694

(22) Filed: Jan. 19, 2011

Related U.S. Application Data
(60) Provisional application No. 61/297,396, filed on Jan. 22, 2010.

(51) Int. Cl. G01R 31/02

(52) U.S. Cl. 324/543

(57) ABSTRACT

Systems and methods for detecting a fault in an electronic conductor are provided. Electronic parameter measurements are combined with reflectometry profiles to determine when faults are present on the electronic conductor.

This application claims the benefit of U.S. Provisional Patent Application Ser. No. 61/297,396 entitled “Method and System for Arc Fault Detection with Wire Fault Location” filed on 22 Jan. 2010, which is herein incorporated by reference.

### FIELD

The present application relates to fault detection. More particularly, the present application relates to fault detection in an electronic conductor using combined reflectometry and electronic parameter measurement.

### BACKGROUND

Failures in electronic conductors can be pernicious. As one example, the arcing of an electrical short circuit can start a fire. Failures in the wiring of an aircraft or automobile can have dire consequences.

In recognition of the risks posed by failures in electronic conductors, many electronic systems include protective devices, such as circuit breakers, to mitigate the risks posed by some types of failures. While circuit breakers, and more recently, arc-fault circuit breakers, can mitigate some risks associated with short circuits, other types of failures are difficult to detect. Moreover, when intermittent failures cause a circuit breaker to trip, it can be difficult to determine the cause or location of the failure. It can be difficult to determine the cause or location of failure unless the electronic conductor is within its normal operating environment (e.g., actual signals present on the electronic conductor, operational temperature, humidity, vibration environment, etc.).

### SUMMARY

In some embodiments of the invention a method of detecting a fault in an electronic conductor is provided. The method can include obtaining a measurement of an electronic parameter. The electronic parameter can be a current flowing in the electronic conductor, a voltage present on the electronic conductor, or both. Another operation in the method can be obtaining a reflectometry profile of the electronic conductor. The reflectometry profile can include a characterization of the electronic conductor at a same time as the measurement of the electronic parameter. The method can include using the measurement of the electronic parameter in combination with the reflectometry profile to determine when a fault is present on the electronic conductor.

In some embodiments of the invention, a system for detecting a fault in an electronic conductor is provided. The system can include a means for obtaining a measurement of an electronic parameter. The system can also include a means for obtaining a reflectometry profile of the electronic conductor. The measurement of the electronic parameter and the reflectometry profile can characterize the electronic conductor for a same time. The system can also include a means for determining when a fault is present in the electronic conductor using both the measurement of the electronic parameter and the reflectometry profile.

In some embodiments of the invention, a system for detecting a fault in an electronic conductor is provided. The system can include a reflectometer, a measurement unit, and a processing circuit. The reflectometer and measurement unit can be capable of being coupled to an electronic conductor. The reflectometer can inject a test signal into the electronic conductor and obtain a reflectometry profile. The measurement unit can obtain an electronic parameter measurement (current, voltage, or both) at the same time the reflectometer is obtaining a reflectometry profile. The processing circuit can combine the reflectometry profile and the electronic parameter measurement to determine a fault condition. The processing circuit can provide a fault output.

### BRIEF DESCRIPTION OF THE DRAWINGS

Additional features and advantages of the invention will be apparent from the detailed description that follows, taken in conjunction with the accompanying drawings, that together illustrate, by way of example, features of the invention; and, wherein:

FIG. 1 is a block diagram of a system for detecting faults in an electronic conductor in accordance with some embodiments of the present invention.

FIG. 2 is a block diagram of another system for detecting faults in an electronic conductor which provides an improved circuit breaker in accordance with some embodiments of the present invention.

FIG. 3 is a block diagram of a computer system which can be used to implement a processing circuit in accordance with some embodiments of the present invention.

FIG. 4 is a flow chart of a method for detecting a fault in an electronic conductor in accordance with some embodiments of the present invention.

FIG. 5 is a graph of an example fault event showing electronic parameter measurements and reflectometry profile windows in accordance with some embodiments of the present invention.

FIG. 6 is a flow chart of another embodiment of a method of detecting a fault in an electronic conductor in accordance with some embodiments of the present invention.

FIG. 7 is block diagram of another system for detecting faults within an electronic conductor in accordance with some embodiments of the present invention.

### DETAILED DESCRIPTION

Reference will now be made to the exemplary embodiments illustrated in the drawings, and specific language will be used herein to describe the same. It will nevertheless be understood that no limitation of the scope of the invention is thereby intended. Alterations and further modifications of the inventive features illustrated herein, and additional applications of the principles of the inventions as illustrated herein, which would occur to one skilled in the relevant art and having possession of this disclosure, are to be considered within the scope of the invention.

In describing the present invention, the following terminology will be used:

The singular forms “a,” “an,” and “the” include plural referents unless the context clearly dictates otherwise. Thus, for example, reference to an item includes reference to one or more items.

The term “ones” refers to one, two, or more, and generally applies to the selection of some or all of a quantity. The term “plurality” refers to two or more of an item.

As used herein, the term “about” means quantities, dimensions, sizes, formulations, parameters, shapes and other characteristics need not be exact, but may be approximated and/or larger or smaller, as desired, reflecting acceptable tolerances, conversion factors, rounding off, measurement error and the like and other factors known to those of skill in the art.

As used herein, the term “substantially” means that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic, parameter, or value was intended to provide.

Numerical data may be expressed or presented herein in a range format. It is to be understood that such a range format is used merely for convenience and brevity and thus should be interpreted flexibly to include not only the numerical values explicitly recited as the limits of the range, but also interpreted to include all of the individual numerical values or sub-ranges encompassed within that range as if each numerical value and sub-range is explicitly recited. As an illustration, a numerical range of “about 1 to 5” should be interpreted to include not only the explicitly recited values of about 1 to about 5, but also include individual values and sub-ranges within the indicated range. Thus, included in this numerical range are individual values such as 2, 3 and 4 and sub-ranges such as 1-3, 2-4 and 3-5, etc. This same principle applies to ranges reciting only one numerical value (e.g., “greater than about 1”) and applies regardless of the breadth of the range or the characteristics being described.

As used herein, a plurality of items may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. Furthermore, where the terms “and” and “or” are used in conjunction with a list of items, they are to be interpreted broadly, in that any one or more of the listed items may be used alone or in combination with other listed items.

As used herein, the term “alternatively” refers to selection of one of two or more alternatives, and is not intended to limit the selection to only those listed alternatives or to only one of the listed alternatives at a time, unless the context clearly indicates otherwise.

Turning to FIG. 1, a system for detecting faults in an electronic conductor is illustrated in accordance with some embodiments of the present invention. The system, shown generally at 100, can be coupled to an electronic conductor 150 for testing. Various ways of coupling the system to the electronic conductor can be used, for example, as described in further detail below.

The system 100 can include a means for obtaining a measurement of an electronic parameter. For example, in some embodiments, the means for obtaining a measurement of an electronic parameter can be a measurement unit 102. The measurement unit can provide for a measurement 110 of current flowing through the electronic conductor 150, voltage of the electronic conductor, or both.

The current/voltage can be caused by a signal which the electronic conductor is intended to carry. In other words, the electronic conductor need not be deenergized or otherwise placed out of service when the system 100 is operating. Thus, a live (operational) signal can be present in the electronic conductor, and the current/voltage measurement can be of the signal. For example, the signal can be an alternating current signal being used to supply power to a load through the electronic conductor.

Various ways of measuring current and voltage can be used. For example, the current can be detected by inserting a small series resistance into the electronic conductor and measuring a voltage drop across the small series resistance with a voltmeter. As another example, the current can be detected by measuring the magnetic field induced by the current through the electronic conductor (e.g., using a Hall effect sensor). Various types of current and voltage sensors are commercially available which can be used. The invention is not limited to the foregoing examples, and other techniques for measuring current and/or voltage can be used as well.

The system 100 can also include a means for obtaining a reflectometry profile of the electronic conductor. For example, in some embodiments, the means for obtaining a reflectometry profile can be a reflectometer 104. The reflectometer can inject a test signal into the electronic conductor and obtain a reflectometry profile 112 based on reflections of the test signal produced within the electronic conductor. Various types of reflectometers can be used including by way of example and not limitation: spread spectrum reflectometers, spread spectrum time domain reflectometers, time domain reflectometers, frequency domain reflectometers, and the like. For example, a spread spectrum reflectometry profile can be obtained by injecting a spread spectrum signal into the electronic conductor, and correlating the injected spread spectrum signal with a return signal extracted from the electronic conductor to obtain a correlation. For example, the correlation can include integrating the product of the injected spread spectrum signal with the return signal over a variety of different delays to obtain a correlation profile. The correlation profile can be provided as the reflectometry profile.

The electronic parameter measurement 110 and the reflectometry profile 112 can be made at the same time. For example, one or more measurements of the electronic parameter can be made during a time window corresponding to the characterization of the electronic conductor produced by the reflectometry profile. Various techniques for time-aligning the parameter measurement and reflectometry profile can be used, for example, as discussed in further detail below.

The system 100 can also include a means for determining when a fault is present in the electronic conductor using both the measurement of the electronic parameter and the reflectometry profile. For example, in some embodiments, the means for determining when a fault is present can be a processing circuit 106. The processing circuit can combine the reflectometry profile and the electronic parameter measurement to determine a fault condition. For example, the combining can be as described in further detail below. The processing circuit can provide a fault output 108 to provide a fault indication when a fault condition is detected. Various ways of implementing the processing circuit can be used as described in further detail below.

Various ways of coupling the system 100 to the electronic conductor 150 can be used. For example, as shown in the illustrated of FIG. 1, the system can be attached to the electronic conductor at an injection point 152. As another example, the system can be integrated into a handheld test instrument. The handheld test instrument can also provide the ability to make other types of electrical measurements (e.g., voltmeter, Ohmmeter, etc.).

The system 100 can also be integrated into an operational network, such as for example, a utility power distribution network, a public communication network, an aircraft electrical subsystem, etc.

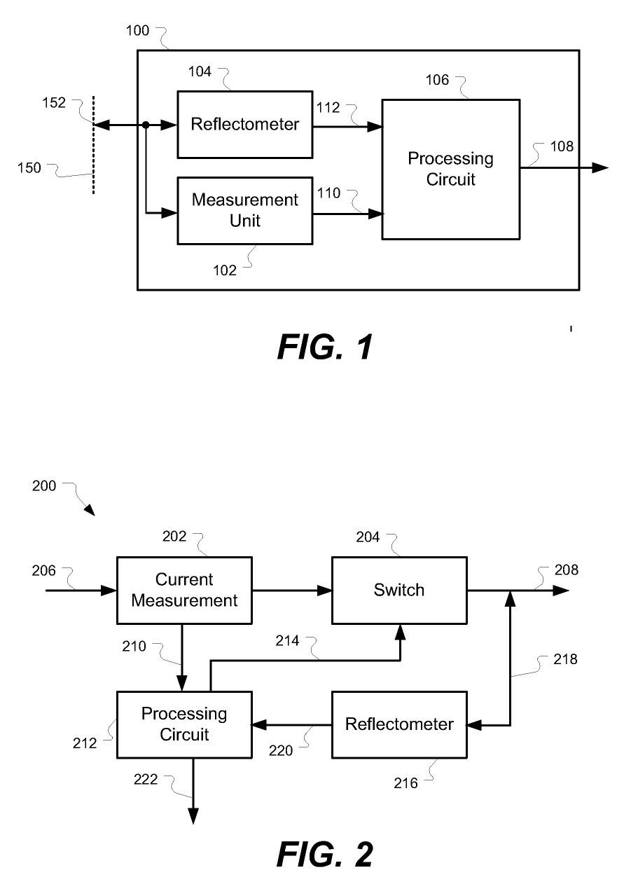

FIG. 2 illustrates an embodiment of the system which can provide an improved electrical circuit breaker 200. The system can be inserted into an electrical line, connected at a line in 206 and line out 208. For example, the electrical line can be a utility power line (e.g., overhead or underground transmission line), a public communication line (e.g., a telephone local loop or interoffice line), a wire within a wiring harness (e.g., within an aircraft or vehicle electronic subsystem), or the like. The electrical line can carry alternating current power from a source to a load, direct current power, communications signals, control signals, or other electrical signals.

The improved circuit breaker 200 can include a current measurement device 202 and a switch 204. The current measurement device can measure current flowing from the line in 206 to the line out 208 and provide a current measurement result 210 to a processing circuit 212. The processing circuit can control the switch via a control output 214. For example, in some embodiments, the processing circuit can cause the switch to open when the current exceeds a predefined threshold (i.e., operating similarly to a conventional circuit breaker). The switch can be any suitable type of switch for opening a line carrying a high current (i.e., a switch suitable for use in a circuit breaker).

The improved circuit breaker 200 can also include reflectometer 216. The reflectometer can have one or more connections 218 to the line out 208. The reflectometer can obtain a reflectometry profile of the line out, for example, as described above. The reflectometry profile 220 can be provided to the processing circuit 212.

In some embodiments, the processing circuit can combine the reflectometry profile 220 and the current measurement 210 to determine when a fault condition exists. When a fault condition exists, the control output 214 can be activated to open switch 204, disconnecting the line out from the line in.

The processing circuit 212 can also provide a fault output 222. For example, the fault output can be an indicator light, an electrical signal, a wireless signal, or any other suitable means for communicating fault information. In some embodiments, the fault output 222 can be connected to either the line in 206 or line out 208 to allow suitable formatted fault information to be communicated via the line in or line out. For example, the fault output information can be encoded in a radiofrequency signal, coupled to the line in or line out (e.g., directly or through a capacitor or inductor), and the radiofrequency signal propagated over power distribution wiring to communicate the fault information to some other system. As another example, the fault output information can be a spread spectrum signal designed to not interfere with normal signals operationally present on the line in and line out.

Because the reflectometer 216 is located on the line out 208 side of the switch 204, the reflectometer can continue to obtain reflectometry profiles of the line out even when the switch has been opened. This can be helpful in troubleshooting the cause of the failure. For example, in some embodiments, the reflectometer can be used to provide a distance to fault. In some embodiments, the reflectometer can be used to continue to monitor the line after the fault event, and when the fault is cleared, automatically close the switch to restore normal operation.

Various ways of implementing a processing circuit (e.g., processing circuit 106 (FIG. 1) or processing circuit 212 (FIG. 2)) can be used. For example, in some embodiments, the processing circuit can be implemented in digital hardware, such as in a field programmable gate array (FPGA), an application specific integrated circuit (ASIC), or discrete logic components. As another example, in some embodiments, the processing circuit can include a computer system.

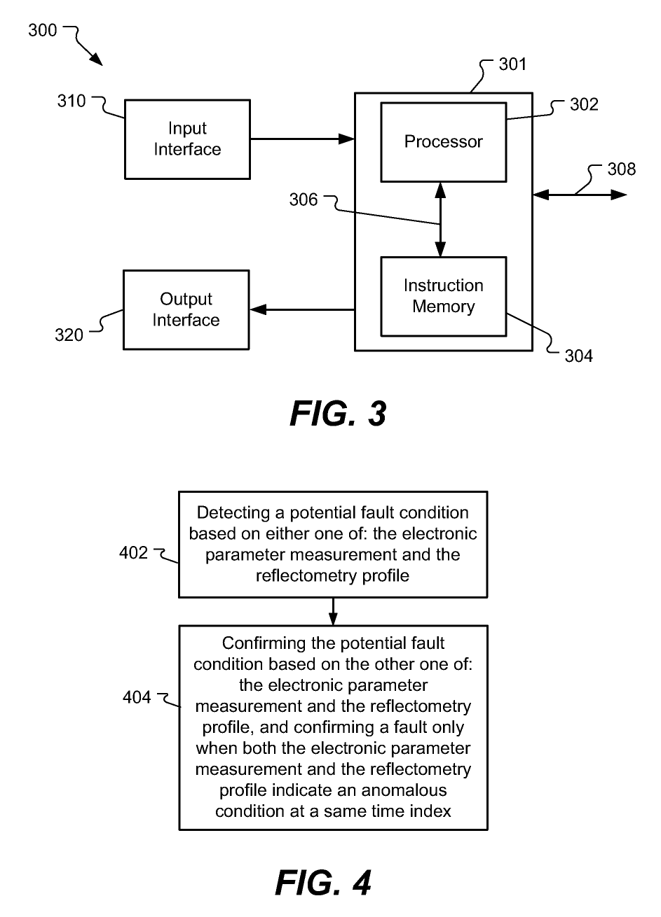

FIG. 3 illustrates one embodiment of a computer system 300 which can be used to implement one or more of the blocks of the processing circuit. The computer system can include a general-purpose or special-purpose processing subsystem 301. For example, the computer system can be a personal computer, a notebook computer, a workstation, a minicomputer, a mainframe, a supercomputer, a multi-processor system, a processor-based electronic device, or the like, which is coupled to the other components of the system 100. The processing subsystem can include a processor 302 and an instruction memory 304. The processor can be capable of executing computer-executable instructions received from the instruction memory via a bus 306 or similar interface. The processor can be a single processor or multiple processors (e.g., a central processor and one or more other processors designed to perform a particular function or task). The instruction memory can be integrated into the same semiconductor device or package as the processor. The bus can be configured to connect various components of the computer system, and can include any of a variety of bus structures including a memory bus or memory controller, a peripheral bus, or a local bus that uses any of a variety of bus architectures. The bus can be used to interconnect the processor, instruction memory, and other components, such as mass storage devices, input/output interfaces, network interfaces, and the like.

As described further below, computer-executable instructions can cause the processor 302 to execute functions to implement various methods. The computer-executable instructions can be permanently stored in the instruction memory 304 or can be temporarily stored in the instruction memory and loaded into the instruction memory from a non-transitory computer-readable medium, for example, via an interface 308. The computer-executable instructions can include data structures, objects, program code, routines, or other program modules that can be accessed by the processor. For example, the computer executable instructions can include operating system instructions used to establish communication or enable loading of programs, such as during start-up of the computer system 300. In general, computer-executable instructions can cause the processor to perform a particular function or group of functions and are examples of program code means for implementing methods disclosed herein. Furthermore, a particular sequence of the executable instructions provides an example of corresponding acts that can be used to implement the operations of such methods.

Examples of computer-readable media include random-access memory (RAM), read-only memory (ROM), programmable read-only memory (PROM), erasable programmable read-only memory (EPROM), electrically-erasable programmable read-only memory (EEPROM), compact disk read-only memory (CD-ROM), digital video disk (DVD), magnetic medium, or other suitable device or component that is capable of providing data or executable instructions that can be accessed by the processor 302. Computer-readable media can be a non-transitory media (e.g., a physical device as described above) which allows for permanent, semi-permanent, or temporary storage of executable instructions.

The computer system 300 can include various input/output interfaces, including for example an input interface 310 and an output interface 320. The input interface can use, for example, a serial interface, a parallel interface, a universal serial bus (USB) interface, a FireWire interface (IEEE 1394), an Ethernet interface (IEEE 802.3, IEEE 802.11), and the like. The output interface can be the same or different than the input interface. The input interface can be used accept (receive) data. For example, input data can be provided from the measurement unit 102 and reflectometer 104. The output interface can be used to provide (transmit) data. For example, output data can be provided to the fault output 108. Initialization or control data (if used) can be output to the measurement unit, data and/or to the reflectometer unit.

In some embodiments, the computer system 300 can be used to implement a method for determining when a fault is present in an electronic conductor in distinct software modules. The software modules can cause the processor 302 to implement the modules.

For example, as illustrated in flow chart form in FIG. 4, in an embodiment the software modules can include a detection module 402 and a confirmation module 404 to implement a method for determining when a fault is present. The detection modulate can detect a potential fault condition based on either an electronic parameter measurement or a reflectometry profile.

In some embodiments, the potential fault condition can be detected when the electronic parameter measurement is outside a defined range. Various ranges can be used. For example, the fault condition can correspond to a current measurement exceeding a maximum current threshold. As another example, the fault condition can correspond to a voltage measurement being less than a minimum voltage threshold. The potential fault condition can be identified for a particular time index (e.g., a particular sample number in a discrete time system).

In some embodiments, the potential fault condition can be detected when a current (most recent in time) reflectometry profile differs from a previous reflectometry profile by more than a threshold. The threshold can be a predetermined value or an adaptive value (e.g., determined based on noise levels or variance of measurements obtaining during a training period). In some embodiments, reflectometry profiles can be repeatedly obtained, and differences between successive profiles compared. As another example, a baseline reflectometry profile can be obtained (e.g., by using one or averaging several profiles) and subsequent profiles compared to the baseline profile. A potential fault condition can be detected when the current reflectometry profile differs from a previous reflectometry profile at a time index. The difference can be required to exceed a threshold. For example, a threshold can be set so that small differences between profiles due to noise or measurement error are ignored. If desired, differences in the reflectometry profile can be ignored that correspond to distances on the wire outside a range of interest. For example, in some embodiments, differences corresponding to distances to a load on the electronic conductor can be ignored, since such changes in the reflectometry profile may correspond to variations in the load rather than an actual fault.

When the detection module 402 has detected a potential fault, the confirmation module 404 can confirm the fault condition based on the other one of the electronic parameter measurement and the reflectometry profile. The fault condition can be declared when both the electronic parameter measurement and the reflectometry profile indicate anomalous conditions at the same time index (or range of time indices). For example, the electronic parameter measurement can be required to indicate an anomalous condition within a time window covered by the reflectometry profile.

If desired, the electronic parameter measurement and the reflectometry profile can also be required to show compatible fault conditions before a fault is declared. For example, in some embodiments, if the current is high (above a threshold) indicative of a short circuit, the reflectometry profile can be required to show a short circuit type anomaly before a fault is declared.

When a potential fault has been detected by the detection module 402, but no confirmation is made by the confirmation module 404, various actions can be taken. In some embodiments, the confirmation module can continue to check for a confirmation of the fault for a period of time. In some embodiments, the potential fault can be logged and operation of the detection module resume. If desired, thresholds or other operating parameters can be adjusted in response to repetitive potential faults (e.g., increasing detection thresholds, decreasing detection thresholds, changing reflectometry parameters to provide greater or lesser resolution, etc.).

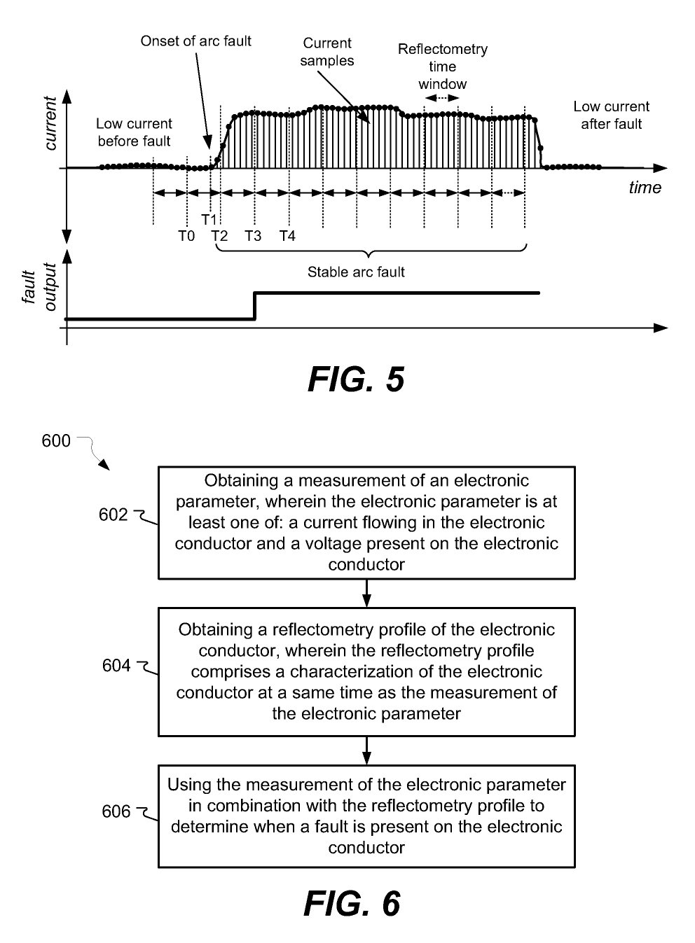

FIG. 5 illustrates one non-limiting example of a fault event. Electronic parameter measurements of the current can occur at a regular sample interval (e.g., every 100 microseconds, 25 microseconds, or other suitable rate). Reflectometry profiles can be obtained over time windows which encompass a number of the electronic parameter measurements (e.g., windows encompassing intervals of 125 microseconds, 600 microseconds, 2 milliseconds, or other suitable rate).

In FIG. 5, it can be seen that the fault begins at time T1. Reflectometry profiles are performed over time intervals T0-T2, T2-T3, etc. Since the fault occurred near the end of the interval T0-T2, the reflectometry profile may or may not indicate a sufficiently large anomaly during that interval. Regardless, during the next time interval T2-T3, the fault is sufficiently large that the reflectometry profile will show the anomaly during the next interval.

Thus, if the current is used for potential fault detection, the initial detection of the fault may be obtained from any current sample after T1. The confirmation may then occur using the reflectometry profile corresponding to either interval T0-T2 (less likely) or during interval T2-T3 (more likely).

Conversely, if the reflectometry profile is used for potential fault detection, the initial detection may occur during either interval T0-T2 or during interval T2-T3. The confirmation can then use current measurements corresponding to the same interval to confirm the fault.

Having detected and confirmed the fault, a fault output can be provided. For example, as shown in FIG. 5, the fault output can be a logic signal which transitions from a logic low (false) state to a logic high (true) state after the detection and confirmation of a fault (shown here as occurring at time T3).

If desired, additional information can be extracted from the electronic parameter measurements and/or reflectometry profile by the processor and output to provide a type of fault or a distance to fault. For example, in some embodiments, the type of fault can be determined as a short circuit or an open circuit based on the voltage and/or current that is measured.

As yet another example, in some embodiments, a distance to the fault can be determined from the reflectometry profile. For example, as described above, the reflectometry profile can be obtained by correlating a signal injected into the electronic conductor. Reflections of the injection signal will be produced at impedance discontinuities in the electronic conductor (e.g., open circuits, short circuits, breaks in insulation, branches, etc.). The reflections propagate back toward the point of injection. Thus, when a correlation is performed, peaks will occur at time offsets corresponding to the round trip propagation delay from the point of injection to the impedance discontinuities. Thus, in principle, the reflectometry profile provides a map of impedance versus distance on the electronic conductor. In practice, however, the actual correlation results are quite complex (as there can be multiple reflections and reflections of widely differing strength). Normally, however, the reflectometry profile is constant, since the electronic conductor characteristics are constant. Hence, changes between a current reflectometry profile and a previous (or baseline) reflectometry profile indicate a change (e.g., fault) in the condition of the wire at the distance corresponding to the point of change.

If desired, multiple confirmations can be used before a fault is declared. For example, a fault can be declared only after it has been observed (in both the reflectometry profile and voltage/current measurement) multiple times. In particular, a fault can be declared after both the electronic parameter measurement and the reflectometry profile have indicated anomalous conditions at a multiple corresponding time indices.

If desired, a series of measurements can be taken and statistical analysis of the measurements can be performed. For example, a fault can be declared based on a single observation (detection and confirmation using both reflectometry and voltage/current measurement). Using multiple observations, additional information about the fault (e.g., location) may be obtained. For example, multiple observations can be averaged together to reduce noise and improve accuracy of the information.

If desired, reflectometry profiles can be discarded when they are suspected to contain invalid or inconsistent data. For example, referring to FIG. 5, the reflectometry profile during time interval T0-T2 is obtained while the current measurements show rapid changes in the current. Hence, the reflectometry profile corresponding to T0-T1 may be discarded, and the later reflectometry profile for T2-T3 used instead.

FIG. 6 illustrates a flow chart of another embodiment of a method of detecting a fault in an electronic conductor. For example, in some embodiments, the method can be implemented by the processing circuit 106 of FIG. 1. The method 600 can include obtaining 602 a measurement of an electronic parameter, wherein the electronic parameter is at least one of: a current flowing in the electronic conductor and a voltage present on the electronic conductor. For example, in some embodiments, a current and/or voltage measuring device can be coupled to the electronic conductor. In some embodiments, obtaining the measurement of an electronic parameter can include receiving data from a measurement unit which provides current and/or voltage information regarding the electronic conductor. For example, high voltage transmission lines can include monitoring equipment which provides sensed voltage and/or current information. As another example, an electronic system to be monitored can include integrated current/voltage sensors to which a fault monitoring system can be interfaced. Thus, the method (or a system implementing the method) need not include components for actually measuring the electronic parameter, and can instead receive the electronic parameter measurement from an external system.

The method 600 can also include obtaining 604 a reflectometry profile of the electronic conductor, wherein the reflectometry profile comprises a characterization of the electronic conductor at a same time as the measurement of the electronic parameter. For example, in some embodiments, a reflectometry instrument can be coupled to the electronic conductor. The coupling can be at a single point or at multiple points (e.g., injecting a spread spectrum signal at an injection point and extracting a response signal at an extraction point). The coupling can be a direct electrical connection (e.g., a direct current connection), an indirect electrical connection (e.g., a capacitive or an inductive coupler), or other type of connection. An electronic system to be monitored can include injection/extraction equipment to which a fault monitoring system can be interfaced.

The obtaining 602 a measurement of an electronic parameter and the obtaining 604 a reflectometry profile of the electronic conductor can occur simultaneously. For example, as described above, a fault monitoring system can include a measurement unit and a reflectometer. The measurement unit and the reflectometer can make periodic measurements of the electronic conductor. One or more samples of the electronic parameter can be made during a time interval corresponding to a reflectometry profile.

Another operation in the method can be using 606 the measurement of the electronic parameter in combination with the reflectometry profile to determine when a fault is present on the electronic conductor. For example, as describe above, in some embodiments, either the electronic parameter or the reflectometry profile can be used to detect a potential fault, and the other can be used to confirm the fault. As another example, the electronic parameter and the reflectometry profile can each be monitored for potential faults, and whenever either one indicates a fault, the other can be used to confirm the fault.

If desired, operation of the method 600 can occur while a live operational signal is present in the electronic conductor. For example, as described above, the electronic conductor can be a power distribution line, and the method can operate while power is being distributed through the line. As additional examples, the electronic conductor can be part of an electronics system which is currently in operation (e.g., an aircraft in flight, a vehicle in motion, etc.). Benefits of performing testing while live can include improved ability to detect intermittent faults. For example, some faults may only occur during particular environmental conditions (e.g., temperature, humidity, vibration) which are present during operation of the system, making such faults difficult to impossible to isolate when the electronic conductor is taken out of service for testing (e.g., the difference between an aircraft in flight and on the ground). As another example, some faults only occur when an operational signal is present, making such faults difficult to isolate when the electronic conductor is taken out of service. By performing live testing, these types of faults may be more accurately detected (and, in some embodiments, information about the faults, e.g. location, can be obtained at the time of detection).

Reflectometry measurements can occur while the live operational signal is present by using a technique (e.g., spread spectrum reflectometry) which is compatible with live testing. For example, spread spectrum reflectometry can use a spread spectrum signal which does not interfere with operational signals present on the electronic conductor. As another example, frequency domain reflectometry can be performed using frequencies over a range outside those used by the electronic system of which the electronic conductor is part.

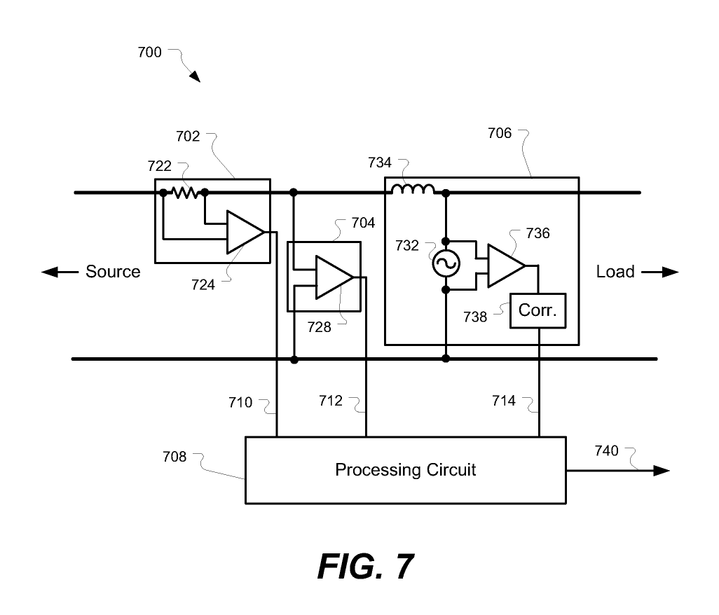

FIG. 7 illustrates an example of a detailed system 700 for detecting faults within an electronic conductor in accordance with some embodiments of the invention. The system can be installed into an electronic conductor, for example, positioned between a source and a load. The system can include a current sensor 702, a voltage sensor 704, and a reflectometer 706. The current measurement 710, voltage measurement 712, and the reflectometry profile 714 can be provided to a processing circuit 708. If desired, either the current sensor or the voltage sensor can be omitted.

In some embodiments, the current sensor 702 can include a series resistor 722 and a differential amplifier 724. The differential amplifier can sense the voltage drop across the series resistor to provide the current measurement 710. Alternatively, other types of current sensors can be used in the system, for example, as described herein. If desired, the current sensor can include filtering (e.g., high pass filtering for preferentially detecting arc-fault conditions).

In some embodiments, the voltage sensor 704 can include a differential amplifier 728. The differential amplifier can sense the voltage to provide the voltage measurement 712. Alternatively, other types of voltage sensors can be used in the system, for example, as described herein.

In some embodiments, the reflectometer 706 can include a signal source 732. For example, the signal source can generate a spread spectrum signal (e.g., a pseudorandom sequence, a pseudorandom sequence modulated onto a radio frequency carrier, a frequency hopped signal, or the like). The spread spectrum signal can be injected into the electronic conductor. If desired, a blocking component, such as an inductor 734, can be used to direct the spread spectrum signal toward the load. Other types of blocking components can be used as well. Moreover, the blocking component can, if desired, alternatively be located on the source side of the voltage sensor 704 or on the source side of the current sensor 702. As shown here, an amplifier 736 can receive the reflected signal (the response of the electronic conductor to the injected spread spectrum signal) in combination with the spread spectrum signal and provide the signal to a correlator 738. Alternatively, if desired, a component such as a directional coupler can be used to separate the injected spread spectrum signal from the reflected signal, and the two signals can be provided separately to the correlator. The correlator can perform an autocorrelation (of the combined signal, as shown here) or a cross correlation (between separate injected and reflected signals) to produce the reflectometry profile 714.

The current measurement 710, voltage measurement 712, and reflectometry profile 714 can be provided to the processing circuit 708 in analog form, and digitized within the processing circuit if desired. Alternatively, any or all of the current sensor 702, voltage sensor 704, and reflectometer 706 can include components (e.g., an analog to digital converter) to provide a digitized current measurement 710, voltage measurement 712, or reflectometry profile 714 to the processing circuit.

The processing circuit 708 can combine the current measurement 710, voltage measurement 712, and reflectometry profile 714 to produce a fault output 740. For example, the processing circuit can operate according to examples described above. If desired, one or more switches (not shown) can be inserted in series into the electronic conductor, and the switches controlled by the processing circuit to allow disconnecting the load from the source when a fault is detected. As another example, if desired, a switch can be inserted in shunt across the electronic conductor near the source end. The switch can be controlled by the processing circuit to provide a crowbar circuit. Various types of switches can be used, including for example, a relay, a thyristor, a triac, or the like. As another example, the fault output can be used to activate other systems (e.g., a fire suppression system), or can provide data which is communicated to a remote location (e.g., via a communications facility or piggy-backed onto the line in or line out).

If desired, the system 700 can include multiple current sensors 702, voltage sensor 704, and reflectometers 706, each coupled to a different electronic conductor to allow monitoring of multiple electronic conductors. A single processing circuit 708 can be connected to multiple sensors/reflectometers to provide for fault detection in the multiple electronic conductors. Alternatively, the system can include multiplexing circuits to allow sharing a current sensor, voltage sensor, or reflectometer among more than one electronic conductor.

If desired, the current sensor 702 or voltage sensor 704 can be used to perform initial potential fault detection, and the reflectometer 706 can be powered off. When a potential fault is detected, the reflectometer can be powered on to perform fault confirmation. Alternatively, the reflectometer can be used to perform initial potential fault detection and the current sensor and/or voltage sensor can be powered off until needed to perform fault confirmation. For example, initial detection and confirmation can proceed as described above.

By combining reflectometry measurements with electronic parameter (e.g., current/voltage) measurements as described herein, various synergistic benefits can be obtained. In general, the strengths and weaknesses of the two techniques can be used to complement each other.

For example, when used alone, current/voltage measurements can be unreliable. In some situations, short duration current spikes are sometimes present due to initial turn-on or turn-off surges when motors are being operated. These current spikes can result in nuisance trips of circuit breakers even through no actual fault is present. The reflectometry profile can be used to distinguish between a current surge initiated at the load (a possibly acceptable surge) from a current surge initiated at some other point in the electronic conductor (a possible fault).

As another example, sometimes circuit breakers are set to require sustained high currents to trip, for example to avoid nuisance trips. But, if the circuit breaker is too slow, permanent damage to the electronic conductor can occur before the circuit breaker has tripped. Using reflectometry to confirm a fault before tripping the circuit breaker can allow increased sensitivity, allowing for trips before damage to the electronic conductor occurs. Nuisance trips can nonetheless be avoided because the reflectometry measurement can be used to confirm the failure.

When used alone, reflectometry measurements can be difficult to interpret. This can be particularly true when an electronic conductor has branches. For example, a reflectometry profile can have many small correlation peaks corresponding to multiple reflections in the line. A failure can result in a small additional peak which is difficult to distinguish. However, in some embodiments, by observing only the differences in successive reflectometry profiles, identification of changes in the electronic conductor can be more easily identified. Instead of making extensive analysis of the reflectometry profile, a simple comparison identifies potential changes, and confirmation of the fault can be made using simple threshold measurements of current/voltage. Accordingly, much of the complexity associated with reflectometry processing can be avoided. For example, the reflectometry profile can be the raw results of the correlation between the injected signal and the response signal, and processing complexity associated with averaging and analyzing the reflectometry response can be avoided.

From another point of view, reflectometry profiles can provide valuable information regarding locations along the electronic conductor (i.e., “where” a fault may be occurring), but the information regarding what is happening at those locations is less reliable (i.e., “what” the fault might be). In contrast, current/voltage measurements can provide valuable information regarding what is happening within the electronic conductor (i.e., “what” the fault might be), but the information regarding where something is occurring (i.e., “where” the fault might be) is less reliable. By simultaneously considering both the “what” and the “where” more reliable fault detection can be obtained.

Turning to a particular example, an arc fault may start at relatively low current level. Because the current level is low, conventional current measurements cannot detect the start of the arc fault. The small increases in current alone would be insufficient to reliably declare a fault. The arc fault will, however, produce a change in the reflectometry profile at a distance corresponding to the distance to the fault. The changes can, however, be highly variable (e.g., as the arc initiates and extinguishes due to vibration, changing voltage, or other factors). Accordingly, it can be difficult to distinguish the fault from noise when considering just the reflectometry profile. By using the combination of current measurements and changes in the reflectometry profile, such a fault can be more reliably detected. Thus, the short circuit fault can be confirmed when changes are observed in the reflectometry profile at corresponding times to the current increase, even though the current alone was insufficient to reliably declare a fault.

As another example, a connector which corrodes over time is an example of a pending open circuit fault. The connector may provide a slowly increasing impedance, or the impedance may occasionally show spikes (e.g., due to vibration or environmental effects). Only small voltage and current changes are likely to be measured until the connector fully fails. The small changes in impedance can be, however, measured by the reflectometry instrument. Thus the reflectometry instrument can be used to detect the impending failure. Analysis of the full reflectometry profile may not be needed, however, since observation of voltage/current changes at the times the reflectometry profile shows changes can be sufficient to confirm the presence of the failing connector. Thus, this type of failing connector may be detected even before a complete open circuit fault has occurred.

Another benefit of the combined presently disclosed techniques is the fine time precision of simple voltage and/or current measurements can be combined with the fine distance precision of the reflectometry measurement. For example, to obtain a reflectometry profile, a number of samples in time can be used to develop the correlation profile. In contrast, current/voltage measurements can be made on a single sample. Thus, current/voltage measurements can provide precise timing information related to a fault, however little distance related information is obtained. Conversely, the reflectometry profile can provide precise distance information related to a fault, while less accurate timing information is obtained.

Various examples of arrangements of methods and systems for detecting faults in an electronic conductor have been disclosed. It is to be understood that different arrangements of the components which would occur to a person of ordinary skill in the art can be used in the systems. Moreover, the systems can be used to implement other methods in addition to those disclosed. Moreover, while certain details have been described with respect to specific system arrangements, those details can be applied to other system arrangements as well.

While several illustrative applications have been described, many other applications of the presently disclosed techniques may prove useful. Accordingly, the above-referenced arrangements are illustrative of some applications for the principles of the present invention. It will be apparent to those of ordinary skill in the art that numerous modifications can be made without departing from the principles and concepts of the invention as set forth in the claims.

What is claimed is:

1. A method of detecting a fault in an electronic conductor, the method comprising:
obtaining a measurement of an electronic parameter, wherein the electronic parameter is at least one of: a current flowing in the electronic conductor and a voltage present on the electronic conductor; and
obtaining a reflectometry profile of the electronic conductor, wherein the reflectometry profile comprises a characterization of the electronic conductor at a same time as the measurement of the electronic parameter;
using the measurement of the electronic parameter in combination with the reflectometry profile to determine when a fault is present on the electronic conductor.

2. The method of claim 1, wherein the obtaining a reflectometry profile comprises performing a spread spectrum reflectometry measurement.

3. The method of claim 2, wherein the performing a spread spectrum reflectometry measurement comprises performing a correlation between a spread spectrum signal injected into the electronic conductor and a return signal extracted from the electronic conductor, wherein the result of the correlation is provided as the reflectometry profile.

4. The method of claim 2, wherein the obtaining a measurement of an electronic parameter comprises performing a current measurement.

5. The method of claim 4, wherein the performing a spread spectrum reflectometry measurement and the performing a current measurement occur simultaneously.

6. The method of claim 1, wherein a live operational signal is present in the electronic conductor.

7. The method of claim 1, wherein the using the measurement of the electronic parameter in combination with the reflectometry profile to determine when a fault is present on the electronic conductor comprises:
detecting when a current reflectometry profile differs from a previous reflectometry profile by more than a threshold at a time index; and
declaring a fault when the measurement of the electronic parameter is outside a defined range at the time index.

8. The method of claim 1, wherein the using the measurement of the electronic parameter in combination with the reflectometry profile to determine when a fault is present on the electronic conductor comprises:
detecting when the electronic parameter measurement is outside a defined range at a time index; and
declaring a fault when a current reflectometry profile differs from a previous reflectometry profile by more than a threshold at the time index.

9. The method of claim 8, wherein the declaring a fault further comprises: declaring a fault only when the current reflectometry profile differs from a previous reflectometry profile at a point corresponding to a distance less than a distance to a load on the electronic conductor.

10. The method of claim 1, wherein the using the measurement of the electronic parameter in combination with the reflectometry profile to determine when a fault is present on the electronic conductor comprises:
detecting a potential fault condition based on either one of: the electronic parameter measurement and the reflectometry profile; and
confirming the potential fault condition based on the other one of: the electronic parameter measurement and the reflectometry profile.

11. The method of claim 10, wherein the confirming the potential fault condition further comprises declaring a fault only when the electronic parameter measurement and the reflectometry profile both indicate an anomalous condition at a same time.

12. The method of claim 11, wherein the confirming the potential fault condition further comprises declaring a fault only when the electronic parameter measurement and the reflectometry profile both indicate anomalous conditions at a plurality of corresponding time indexes.

13. The method of claim 11, wherein the confirming the potential fault condition further comprises declaring a fault only when the electronic parameter measurement and the reflectometry profile both indicate a compatible anomalous condition.

14. The method of claim 1, further comprising:
providing a type of fault output, wherein the type of fault is determined from the electronic parameter measurement; and
providing a distance to fault output, wherein the distance to fault is determined from a difference between a current reflectometry profile and a previous reflectometry profile.

15. A system for detecting a fault in an electronic conductor, the system comprising:
a means for obtaining a measurement of an electronic parameter, wherein the electronic parameter is at least one of: a current flowing in the electronic conductor and a voltage present on the electronic conductor; and
a means for obtaining a reflectometry profile of the electronic conductor, wherein the reflectometry profile comprises a characterization of the electronic conductor at a same time as the measurement of the electronic parameter; and
a means for determining when a fault is present in the electronic conductor using both the measurement of the electronic parameter and the reflectometry profile.

16. The system of claim 15, wherein the means for obtaining a reflectometry profile comprises a spread spectrum reflectometer.

17. The system of claim 15, wherein the means for determining when a fault is present comprises:
a processor; and
a non-transitory computer readable medium having computer executable program instructions embodied therein, said computer executable instructions implementing a method for determining when a fault is present in an electronic conductor, wherein the method comprises:
detecting a potential fault condition based on either one of: the electronic parameter measurement and the reflectometry profile; and
confirming the potential fault condition based on the other one of: the electronic parameter measurement and the reflectometry profile, and confirming a fault only when both the electronic parameter measurement and the reflectometry profile indicate an anomalous condition at a same time index.

18. The system of claim 17, wherein the method for determining when a fault is present in an electronic conductor further comprises:
providing a type of fault output, wherein the type of fault is determined from the electronic parameter measurement; and
providing a distance to fault output, wherein the distance to fault is determined from a difference between a current reflectometry profile and a previous reflectometry profile.

19. A system for detecting a fault in an electronic conductor, the system comprising:
a reflectometer capable of being coupled to an electronic conductor at an injection point, the reflectometer configured to inject a test signal into the electronic conductor and obtain a reflectometry profile;
a measurement unit capable of being coupled to the electronic conductor at the injection point, the measurement unit configured to obtain an electronic parameter measurement of at least one of current and voltage at the injection point at the same time the reflectometer is obtaining a reflectometry profile; and
a processing circuit coupled to the reflectometer and the measurement unit, wherein the processing circuit is configured to combine the reflectometry profile and the electronic parameter measurement to determine a fault condition; and
a fault output from the processing circuit configured to provide a fault indication when a fault condition is detected.

20. The system of claim 19, wherein the processing circuit is further configured to:
provide a fault type output, wherein the fault type is determined from the electronic parameter measurement; and
provide a fault distance output, wherein the fault distance is determined from a difference between a current reflectometry profile and a previous reflectometry profile.

21. The system of claim 19, wherein the system is disposed within a handheld test instrument.

22. The system of claim 19, wherein the system is integrated into a utility power distribution network.

23. The system of claim 19, wherein the system is integrated into a public communications network.

24. The system of claim 19, wherein the system is integrated into an aircraft electrical subsystem.
